(19) United States
(12) Patent Application Publication
(10) Pub. No.: US 2015/0206852 A1
(43) Pub. Date: Jul. 23, 2015

(54) COPPER CLAD LAMINATE HAVING BARRIER STRUCTURE AND METHOD OF MANUFACTURING THE SAME

(71) Applicant: LINGSEN PRECISION INDUSTRIES, LTD., Taichung City (TW)

(72) Inventors: Tzu-Chih LIN, Taichung City (TW); Chien-Ko LIAO, Taichung City (TW)

(73) Assignee: LINGSEN PRECISION INDUSTRIES, LTD., Taichung City (TW)

(21) Appl. No.: 14/262,199

(22) Filed: Apr. 25, 2014

(30) Foreign Application Priority Data
Jan. 17, 2014 (TW) 103101847

(51) Int. Cl. H01L 23/00; H05K 1/03; H01L 23/498

(52) U.S. Cl. CPC H01L 24/83; H01L 24/27; H01L 24/32; H01L 23/49838; H05K 1/0306; H01L 2224/83815; H01L 2224/29147; H01L 2224/2745; H01L 2224/275; H01L 2224/32225; H05K 2201/09036; H05K 2201/09045

(57) ABSTRACT

A copper clad laminate is disclosed to include a substrate defining a plurality of carrier zones for attachment of chips and having a plurality of barrier portions each arranged around at least one of the carrier zones for isolating the carrier zones. Thus, when tin sheets mounted between the chips and the carrier zones of the substrate become liquids in a thermal reflow process, the barrier portions of the substrate will stop an overflow of molten tin to prevent the chips from damage caused by a solder bridge problem.

### BACKGROUND OF THE INVENTION

1. Field of the Invention

The present invention relates generally to the semiconductor technology, especially related to a copper clad laminate and its manufacturing process.

2. Description of the Related Art

In the field of semiconductor technology, the chip is electrically connected to a substrate through a plurality of solder bumps that are arranged in a matrix. As far as the substrate is concerned, a solder mask is applied to the conductive traces for protection against oxidation, and a plurality of soldering pads are respectively connected with the conductive traces and exposed out of the solder mask. Thus, when the chip is mounted to the substrate, the solder bumps of the chip and the soldering pads of the substrate are interconnected together, such that the signals can be transmitted from the chip to an external electronic device through the soldering bumps of the chip, the soldering pads of the substrate, and the conductive traces of the substrate.

A conventional substrate 1 is shown in FIG. 1, comprising a resin layer 4 and a solder mask 2 coated on the outer surface of the resin layer 4. The solder mask 2 has a plurality of openings 3 smaller in dimension than soldering pads 5 mounted on the resin layer 4, such that the soldering pads 5 are partially covered by the solder mask 2. In the flip-chip technology, a plurality of solder bumps 8 are deposited on the chip pads 7 formed on the top side of the chip 6, and then the chip 6 is flipped over so that the top surface of the chip 6 faces down to enable the chip pads 7 to be aligned with the soldering pads 5 of the substrate 1, and then the solder bumps 8 are reflowed to complete the interconnection between the chip 6 and the substrate 1. In order to strengthen the solder joint, an insulating adhesive can be used to fill the bottom clearances of the chips 6 by an underfill process or compression molding process. However, when the aforesaid chip package is applied to a high power module, high thermal energy will be generated in the chip package under high-voltage current conditions. Accordingly, it is important to improve the thermal dissipation of the chip 6 and the structural stability of the chip 6.

Referring to FIG. 2, to solve the aforementioned problems, the chip 6 is electrically connected to the substrate 1 through a tin sheet 9 that is mounted between the substrate 1 and the chip 6 by a thermal reflow process. However, the tin sheet 9 will become liquid during the thermal reflow process and then the molten tin may flow toward the conductive traces along the outer surface of the substrate 1, such that a solder bridge occurs when the adjacent conductive traces are connected together, resulting in damage of the chip 6. Obviously, it will take a lot of time, effort, and money to repair the damaged chip 6.

Therefore, it is desirable to provide an improved substrate that eliminates the aforesaid drawback.

### SUMMARY OF THE INVENTION

It is one objective of the present invention to provide a copper clad laminate, which can prevent a solder bridge during a thermal reflow process.

To achieve this objective of the present invention, the copper clad laminate comprises a substrate defining a carrier zone adapted for attachment of a chip, and having a barrier portion arranged around the carrier zone for isolating the carrier zone.

Preferably, the substrate can be provided with a plurality of the carrier zones and a plurality of the barrier portions.

Preferably, at least one conductive sheet can be attached between the chip and the carrier zone of the substrate for enabling the chip to be electrically connected to the substrate.

Preferably, a groove or dam can be defined as the barrier portion of the substrate.

Preferably, the substrate is constructed with a ceramic layer and a copper layer coated on top and bottom sides of the ceramic layer.

To achieve this objective of the present invention, a method of manufacturing the copper clad laminate comprises the steps of a) providing the substrate defining the carrier zone and having the barrier portion arranged around the carrier zone, and b) electrically connecting the chip to the carrier zone of the substrate.

Preferably, the barrier portion is embodied as a groove formed by exposure, development, and etching processes.

Preferably, the barrier portion is embodied as a dam formed by a deposition or sputtering process

Preferably, the chip is electrically connected to the substrate through a conductive sheet mounted between the substrate and the chip by a thermal reflow process.

By the aforesaid design, the copper clad laminate of the present invention provides a flat position for the chip and has high thermal conductivity to improve work efficiency of the chip. Further, the copper clad laminate of the present invention uses the barrier portion to prevent the solder bridge during the thermal reflow process.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a sectional view of a chip package according to a prior art.

FIG. 2 is a sectional view of a chip package according to another prior art.

FIG. 3 is a sectional view of a copper clad laminate according to a first embodiment of the present invention, showing that the barrier portion of the substrate is a groove.

FIG. 4 is similar to FIG. 3, but showing that the barrier portion of the substrate is a dam.

FIG. 5 is a top view of the copper clad laminate according to a second embodiment of the present invention.

FIG. 6 is a sectional view of the copper clad laminate according to the second embodiment of the present invention, showing that the barrier portion of the substrate is a groove located between the two adjacent chips.

FIG. 7 is a sectional view of the copper clad laminate according to the second embodiment of the present invention, showing that the barrier portion of the substrate is a dam located between the two adjacent chips.

FIGS. 8A˜8D are schematic drawings showing steps of a method of manufacturing the copper clad laminate, showing the barrier portion of the substrate is formed by exposure, development, and etching processes.

FIGS. 9A˜9D are schematic drawings showing steps of a method of manufacturing the copper clad laminate, showing the barrier portion of the substrate is formed by a deposition process or sputtering process.

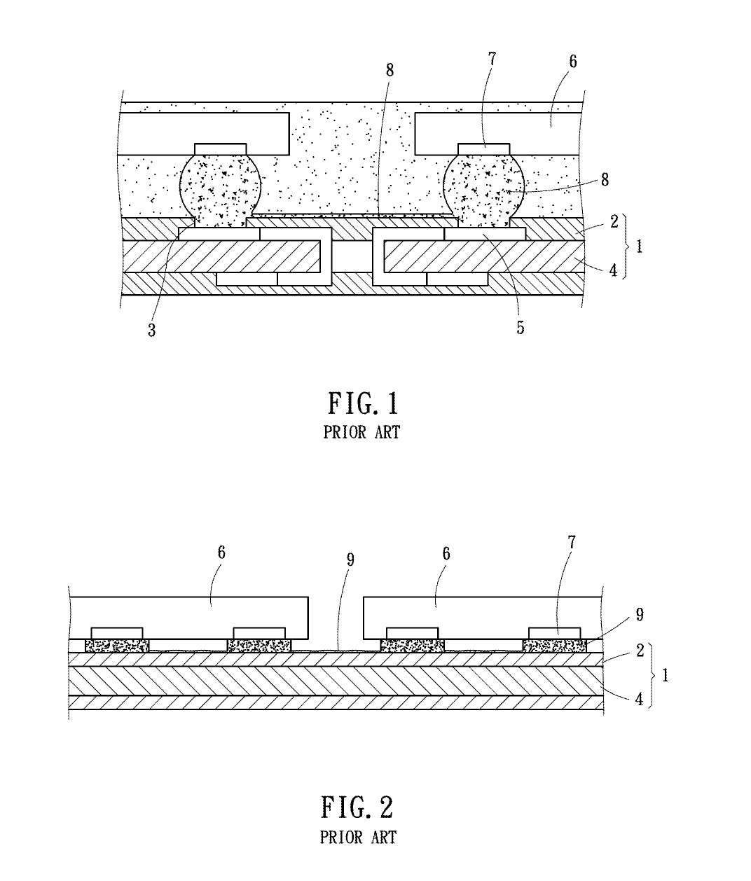

### DETAILED DESCRIPTION OF THE INVENTION

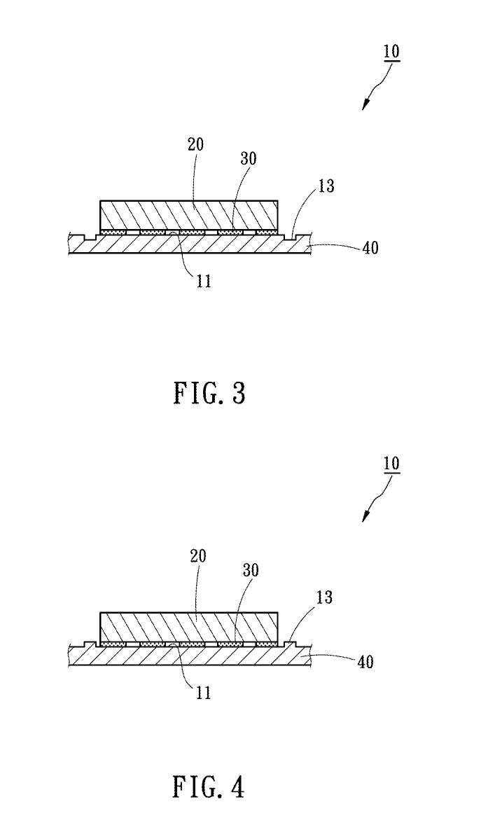

As shown in FIGS. 3 to 4, a cooper clad laminate 10 in accordance with a first embodiment of the present invention comprises a substrate 40 defining a carrier zone 11 and having a barrier portion 13 arranged around the carrier zone 11 for isolating the carrier zone 11. The barrier portion 13 of the substrate 40 can be formed as a groove or dam according to actual manufacturing needs. Further, a conductive sheet 30 is made of tin and mounted to the carrier zone 11 of the substrate 40 for enabling the chip 30 to be electrically connected to the substrate 40. By this way, the chip 20 can be attached evenly to the substrate 40 through the conductive sheet 30, and meanwhile the barrier portion 13 of the substrate 40 can stop the liquefied conductive sheet 30 flowing out of the carrier zone 11 of the substrate 40 for preventing a solder bridge caused by connection between molten tin and conductive traces.

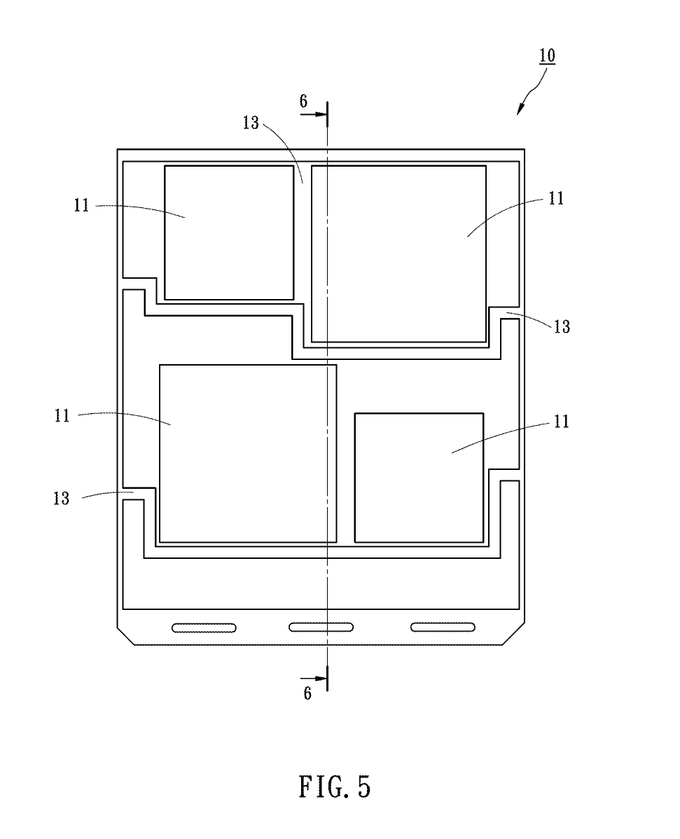

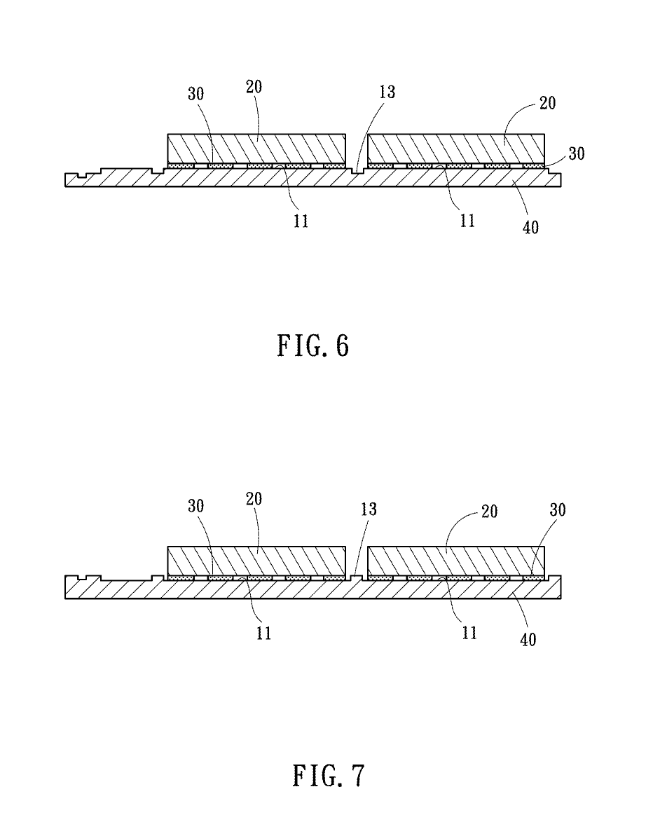

To deserve to be mentioned, the number of the carrier portion 11 and the number of the barrier portion 13 can be adjustable. As shown in FIGS. 5 to 7, a cooper clad laminate 10 in accordance with a second embodiment of the present invention comprises a substrate 40 defining a plurality of the carrier zones 11 and having a plurality of the barrier portions 13 each arranged around one of the carrier zones 11. Furthermore, in order to interconnect a plurality of the chips 20 and the substrate 40 together, a plurality of the conductive sheets 30 are mounted between the chips 20 and the carrier zones 11 of the substrate 40.

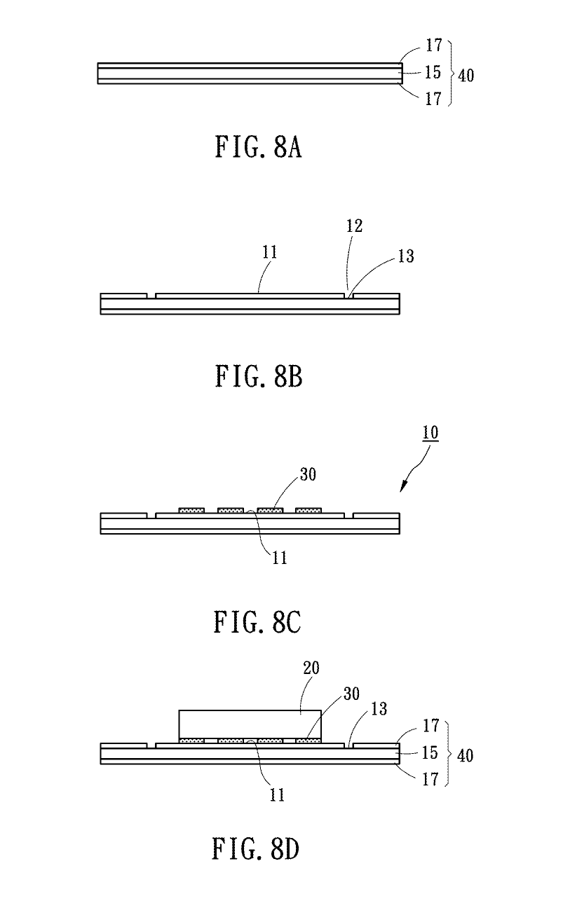

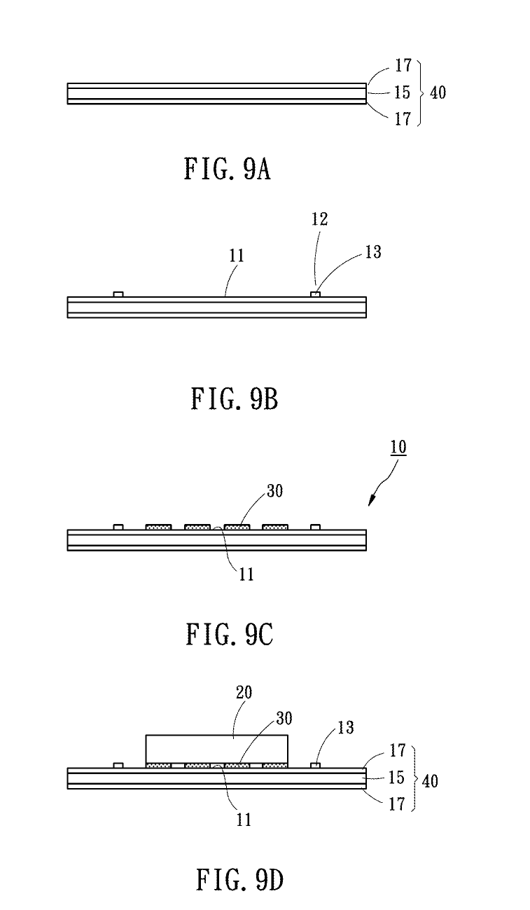

As shown in FIGS. 8A and 9A, the substrate 40 is constructed with a ceramic layer 15 and a copper layer 17 coated on top and bottom sides of the ceramic layer 15, such that the substrate 40 provides great thermal dissipation and excellent electrical conductivity for the chip 20 to avoid excessive heat caused by intensive layout arrangements and high power consumption per unit area.

As shown in FIGS. 8A to 8D, a method of manufacturing the copper clad laminate 10 comprises the following steps.

a) Define the carrier zone 11 and a barrier zone 12 on the substrate 40 by exposure and development processes, and then create a groove arranged around the carrier zone 11 by an etching process to form the barrier portion 13. In this preferred embodiment of the present invention, the substrate 40 is composed of the ceramic layer 15 and the copper layer 17 coated on the top and bottom sides of the ceramic layer 15.

b) Put the conductive sheet 30 on the carrier zone 11 of the substrate 40, and then put the chip 20 on the conductive sheet 30, such that the chip 20 is electrically connected to the substrate 40 through the conductive sheet 30 by a thermal reflow process.

As shown in FIGS. 9A to 9D, another method of manufacturing the copper clad laminate 10 comprises the following steps.

a) Define the carrier zone 11 and the barrier zone 12 on the substrate 40 by exposure and development processes, and then create a dam arranged around the carrier zone 11 by a deposition or sputtering process to form the barrier portion 13.

b) Put the conductive sheet 30 on the carrier zone 11 of the substrate 40, and then put the chip 20 on the conductive sheet 30, such that the chip 20 is electrically connected to the substrate 40 through the conductive sheet 30 by the thermal reflow process.

Accordingly, the copper clad laminate 10 of the present invention provides a flat position for the chip 20 and has great thermal conductivity to improve work efficiency of the chip 20. Further, the copper clad laminate 10 of the present invention uses the barrier portion 13 to prevent the solder bridges caused by the connection between the liquefied conductive sheets 30 and the conductive traces.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A copper clad laminate comprising:
a substrate defining at least one carrier zone for attachment of a chip, and having at least one barrier portion arranged around the carrier zone.

2. The copper clad laminate as claimed in claim 1, further comprising at least one conductive sheet mounted on the carrier zone of the substrate for enabling the chip to be electrically connected to the substrate.

3. The copper clad laminate as claimed in claim 1, wherein the substrate defines a plurality of the carrier zones and has a plurality of the barrier portions each arranged around one of the carrier zones.

4. The copper clad laminate as claimed in claim 3, further comprising a plurality of conductive sheets each mounted on one of the carrier zones of the substrate for enabling a plurality of the chips to be electrically connected to the substrate.

5. The copper clad laminate as claimed in claim 1, wherein the barrier portion of the substrate is a groove.

6. The copper clad laminate as claimed in claim 1, wherein the barrier portion of the substrate is a dam.

7. The copper clad laminate as claimed in claim 1, wherein the substrate has a ceramic layer and a copper layer coated on top and bottom sides of the ceramic layer.

8. A method of manufacturing a copper clad laminate comprising the following steps of:
a) providing a substrate defining at least one carrier zone and having at least one barrier portion arranged around the carrier zone; and
b) electrically connecting a chip to the carrier zone of the substrate.

9. The method as claimed in claim 8, wherein in the step a), the barrier portion is defined as a groove formed by exposure, development, and etching processes.

10. The method as claimed in claim 8, wherein in the step a), the barrier portion is defined as a dam formed by a deposition or sputtering process.

11. The method as claimed in claim 8, wherein in the step a), the substrate has a ceramic layer and a copper layer coated on top and bottom sides of the ceramic layer.

12. The method as claimed in claim 8, wherein in the step b), the chip is electrically connected to the substrate through a conductive sheet mounted between the substrate and the chip by a thermal reflow process.
